(19) United States
(12) Patent Application Publication
(10) Pub. No.: US 2026/0060007 A1
(43) Pub. Date: Feb. 26, 2026

(54) Semiconductor structure with magnetic tunnel junction and inductor

(71) Applicant: UNITED MICROELECTRONICS CORP., Hsin-Chu City (TW)

(72) Inventors: Da-Jun Lin, Kaohsiung City (TW); Fu-yu Tsai, Tainan City (TW); Bin-Siang Tsai, Changhua County (TW)

(73) Assignee: UNITED MICROELECTRONICS CORP., Hsin-Chu City (TW)

(21) Appl. No.: 18/918,017

(22) Filed: Oct. 16, 2024

(30) Foreign Application Priority Data
Aug. 21, 2024 (TW) 113131400

(51) Int. Cl. H10N 50/85; G11C 11/16; H10B 61/00; H10N 50/01

(52) U.S. Cl. CPC H10N 50/85; G11C 11/161; H10B 61/00; H10N 50/01

(57) ABSTRACT

The invention provides a semiconductor structure with magnetic tunnel junction (MTJ) and inductor. The semiconductor structure comprising a substrate, a cell region and an inductor region defined on the substrate, a magnetic tunnel junction (MTJ) is located in the cell region, wherein the MTJ comprises a first MTJ material layer. And an inductor is located in the inductor region, wherein the inductor comprises a multi-layer structure, the multi-layer structure comprises at least one second MTJ material layer, wherein the material of the first MTJ material layer is the same as that of the second MTJ material layer, and viewed from a sectional view, the first MTJ material layer extends along a horizontal direction, and the second MTJ material layer comprises a horizontal part and two vertical parts, and the vertical part extends along a vertical direction.

### BACKGROUND OF THE INVENTION

### 1. Field of the Invention

The present invention relates to a semiconductor structure integrating a magnetoresistive random access memory (MRAM) and an inductor and a manufacturing method thereof, in particular to a semiconductor structure including an inductor capable of storing high magnetic energy and a manufacturing method thereof.

### 2. Description of the Prior Art

Many modern electronic devices have electronic memories. Electronic memory can be volatile memory or nonvolatile memory. Non-volatile memory can retain the stored data even when there is no power supply, while volatile memory loses its stored data when the power supply disappears. Magnetoresistive random access memory (MRAM) has great development potential in the next generation of non-volatile memory technology because of its advantages over current electronic memory.

At present, MRAM is not integrated with inductors to provide radio frequency (RF) applications. Most inductors are assembled with MRAM in an off-chip way, which increases the cost. However, external inductors need extra area in the circuit board, so if MRAM and inductors can be integrated on a single process and chip, the integration degree can be greatly improved and the cost can be reduced.

### SUMMARY OF THE INVENTION

The invention provides a semiconductor structure comprising a magnetic tunnel junction (MTJ) and an inductor, comprising a substrate, wherein a cell region and an inductor region defined on the substrate are located beside the cell region, a magnetic tunnel junction (MTJ) is located in the cell region, wherein the MTJ comprises a first MTJ material layer, and an inductor is located in the inductor region, wherein the inductor comprises a multilayer structure, wherein the multi-layer structure comprises at least one second MTJ material layer, wherein the material of the first MTJ material layer is the same as that of the second MTJ material layer, and viewed from a sectional view, the first MTJ material layer extends along a horizontal direction, and the second MTJ material layer comprises a horizontal part and two vertical parts, and the vertical part extends along a vertical direction.

The invention also provides a method for manufacturing a semiconductor structure including a magnetic tunnel junction and an inductor, which comprises the following steps: providing a substrate, wherein a cell region and an inductor region defined on the substrate are located beside the cell region, forming a magnetic tunnel junction (MTJ) in the cell region, wherein the MTJ contains a first MTJ material layer, and forming an inductor in the inductor region, wherein the inductor comprises a multi-layer structure, wherein the multi-layer structure comprises at least a second MTJ material layer, wherein the material of the first MTJ material layer is the same as that of the second MTJ material layer, and viewed from a cross section, the first MTJ material layer extends along a horizontal direction, and the second MTJ material layer comprises a horizontal part and two vertical parts, and the vertical part extends along a vertical direction.

The invention provides a semiconductor structure integrated with MRAM and inductor and a manufacturing method thereof. In which an inductor is formed in the process of manufacturing MRAM, so that the process steps can be saved. In addition, the inductors are arranged along the vertical direction and vertically penetrate through the multilayer dielectric layers, thus effectively utilizing the idle space in the stacked dielectric layers. In addition, the inductor of the invention is surrounded by a spiral coil structure, wherein the coil structure is formed by connecting a plurality of notched metal layers and conductive vias in series, so that when the coil structure is electrified, a larger electric field can be generated to improve the magnetic energy stored in the inductor. Therefore, the invention has the effects of improving semiconductor quality and simplifying manufacturing process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

In order to make the following easier to understand, readers can refer to the drawings and their detailed descriptions at the same time when reading the present invention. Through the specific embodiments in the present specification and referring to the corresponding drawings, the specific embodiments of the present invention will be explained in detail, and the working principle of the specific embodiments of the present invention will be expounded. In addition, for the sake of clarity, the features in the drawings may not be drawn to the actual scale, so the dimensions of some features in some drawings may be deliberately enlarged or reduced.

FIGS. 1-8 are schematic cross-sectional views of a semiconductor structure integrated with MRAM and inductor according to an embodiment of the present invention.

FIG. 9 is a top view of the MTJ material layer and the coil structure in the inductor region of the present invention.

FIG. 10 is a schematic diagram showing the structure of the coil structure C of the present invention.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

Although the present invention uses the terms first, second, third, etc. to describe elements, components, regions, layers, and/or sections, it should be understood that such elements, components, regions, layers, and/or sections should not be limited by such terms. These terms are only used to distinguish one element, component, region, layer and/or block from another element, component, region, layer and/or block. They do not imply or represent any previous ordinal number of the element, nor do they represent the arrangement order of one element and another element, or the order of manufacturing methods. Therefore, the first element, component, region, layer or block discussed below can also be referred to as the second element, component, region, layer or block without departing from the specific embodiments of the present invention.

The term “about” or “substantially” mentioned in the present invention usually means within 20% of a given value or range, such as within 10%, or within 5%, or within 3%, or within 2%, or within 1%, or within 0.5%. It should be noted that the quantity provided in the specification is approximate, that is, the meaning of “about” or “substantially” can still be implied without specifying “about”or “substantially”.

The terms “coupling” and “electrical connection” mentioned in the present invention include any direct and indirect means of electrical connection. For example, if the first component is described as being coupled to the second component, it means that the first component can be directly electrically connected to the second component, or indirectly electrically connected to the second component through other devices or connecting means.

Although the invention of the present invention is described below by specific embodiments, the inventive principles of the present invention can also be applied to other embodiments. In addition, in order not to obscure the spirit of the present invention, specific details are omitted, and the omitted details are within the knowledge of those with ordinary knowledge in the technical field.

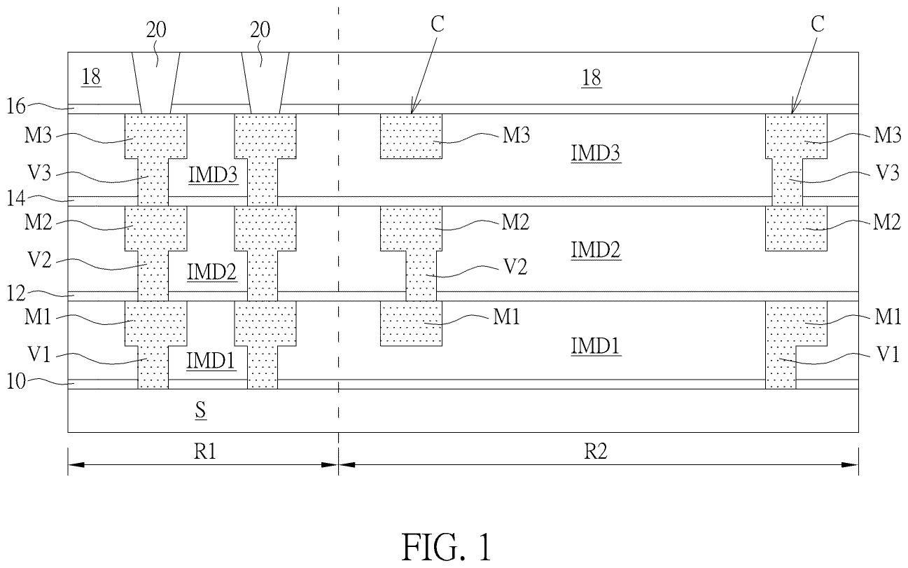

Please refer to FIGS. 1-8, which show schematic cross-sectional structures of a semiconductor structure integrated with MRAM and inductor according to an embodiment of the present invention. As shown in FIG. 1, firstly, a substrate S is provided, such as a silicon substrate or a material layer containing electronic components (such as transistors). A multi-layer structure is sequentially formed on the substrate S. Taking FIG. 1 as an example, it includes a mask layer 10, a first dielectric layer IMD1, a mask layer 12, a second dielectric layer IMD2, a mask layer 14, a third dielectric layer IMD3, a mask layer 16 and a fourth dielectric layer 18. The materials of the first dielectric layer IMD1, the second dielectric layer IMD2, the third dielectric layer IMD3 and the fourth dielectric layer 18 are, for example, silicon oxide, while the materials of the mask layer 10, the mask layer 12, the mask layer 14 and the mask layer 16 are, for example, silicon nitride or silicon oxynitride, but the present invention is not limited to this. In addition, the number of mask layers and dielectric layers shown in FIG. 1 can also be adjusted according to actual needs. In other words, in other embodiments of the present invention, the semiconductor structure may also include more or less mask layers and dielectric layers, and the variations are also within the scope of the present invention.

The mask layer 10 and the first dielectric layer IMD1 contain conductive vias V1 and the first metal layer M1, the mask layer 12 and the second dielectric layer IMD2 contain conductive vias V2 and the second metal layer M2, the mask layer 14 and the third dielectric layer IMD3 contain conductive vias V3 and the third metal layer M3, and the mask layer 16 and the fourth dielectric layer 18 contain conductive vias 20. Here, the conductive vias V1, V2, V3, and the first metal layer M1, the second metal layer M2, and the third metal layer M3 are made of materials with good conductivity, such as tungsten, cobalt, copper, aluminum, gold, silver, etc., wherein the first metal layer M1, the second metal layer M2, and the third metal layer M3 are mainly used for electrically connecting various components in the horizontal direction, that is, electrically connecting various electronic components in the same layer structure. And the main functions of the conductive vias V1, V2, V3 and V4 are to connect electronic components in vertical directions (that is, different layers). The technology of metal layer and conductive via belongs to the known technology in this field, so it will not be described in detail here.

In addition, the semiconductor device in FIG. 1 further includes a cell region R1 and an inductor region R2, wherein the cell region R1 and the inductor region R2 are preferably adjacent to each other. In the following steps, devices such as MRAM will continue to be formed in the cell region R1, and inductors will be formed in the inductor region R2 for storing magnetic energy.

It is worth noting that the conductive vias V1, V2, V3, the first metal layer M1, the second metal layer M2, and the third metal layer M3 in the inductor region R2 together form a spiral coil structure C, wherein the first metal layer M1, the second metal layer M2, and the third metal layer M3 are in a ring or frame structure with openings, and are connected with each other through the conductive vias V1-V3, so as to form a continuous structure, and the characteristics of the coil structure C will be described more clearly in the following paragraphs.

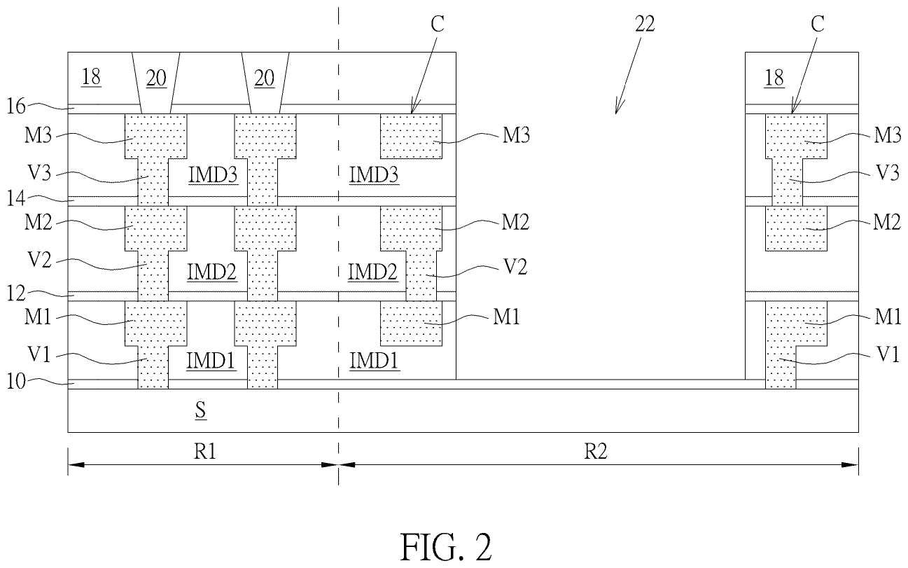

Then, as shown in FIG. 2, an etching process is used to form a groove 22 in the inductor region R2. In this embodiment, the groove 22 sequentially passes through the fourth dielectric layer 18, the mask layer 16, the third dielectric layer IMD3, the mask layer 14, the second dielectric layer IMD2, the mask layer 12 and the first dielectric layer IMD1, exposing the surface of the mask layer 10.

In the next step, an inductor structure will be formed in the groove 22, in which the inductor structure penetrates through the multiple dielectric layers in the vertical direction, so an inductor with a larger area is formed in a limited space, which is beneficial to storing more magnetic energy, and the details will be described in the following paragraphs.

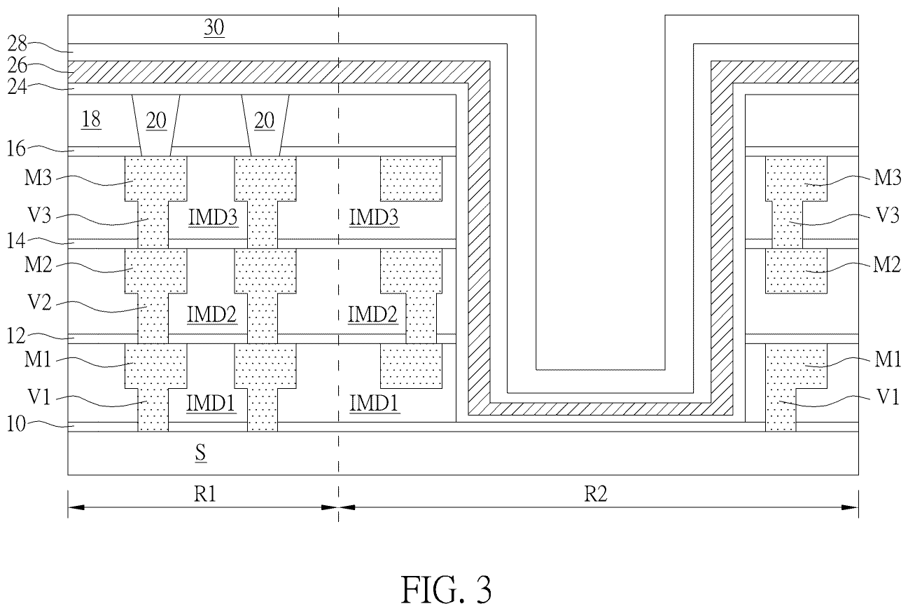

As shown in FIG. 3, a bottom electrode layer 24, an MTJ material layer 26, a top electrode layer 28 and a mask layer 30 are sequentially formed in the cell region R1 and the inductor region R2, wherein the materials of the bottom electrode layer 24 and the top electrode layer 28 are, for example, titanium, titanium nitride, tantalum or tantalum nitride, but are not limited thereto. The function of the bottom electrode layer 24 and the top electrode layer 28 is to electrically connect the subsequently formed magnetic tunneling junction (MTJ). The MTJ material layer 26 will be used as the magnetic tunneling junction (MTJ) of MRAM in the following steps, in which the MTJ material layer 26 may contain multi-layer structures, such as magnetic materials and insulating materials. Common magnetic materials are CoPt (cobalt platinum) alloy, CoFe (cobalt iron) alloy, FePt (iron platinum) alloy, IrMn (iridium manganese) alloy, PtMn (platinum manganese) alloy, Co/Pt multilayer film or Co/Pd multilayer film. Common insulating materials are, for example, MgO (magnesium oxide) or Al₂O₃ (alumina), but the present invention is not limited to this. The main function of the mask layer 30 is to protect the magnetic tunneling junction (MTJ). The material of the mask layer 30 is silicon oxide, for example, but not limited to this.

It is worth noting that the bottom electrode layer 24, the MTJ material layer 26, the top electrode layer 28 and the mask 30 are formed on the surface of the fourth dielectric layer 18 in the cell region R1 and also in the groove 22 in the inductor region R2, that is to say, the above-mentioned material layers will be stacked on the side wall and bottom surface of the groove 22 in sequence, and the cross-sectional view shows a U-shaped cross-section.

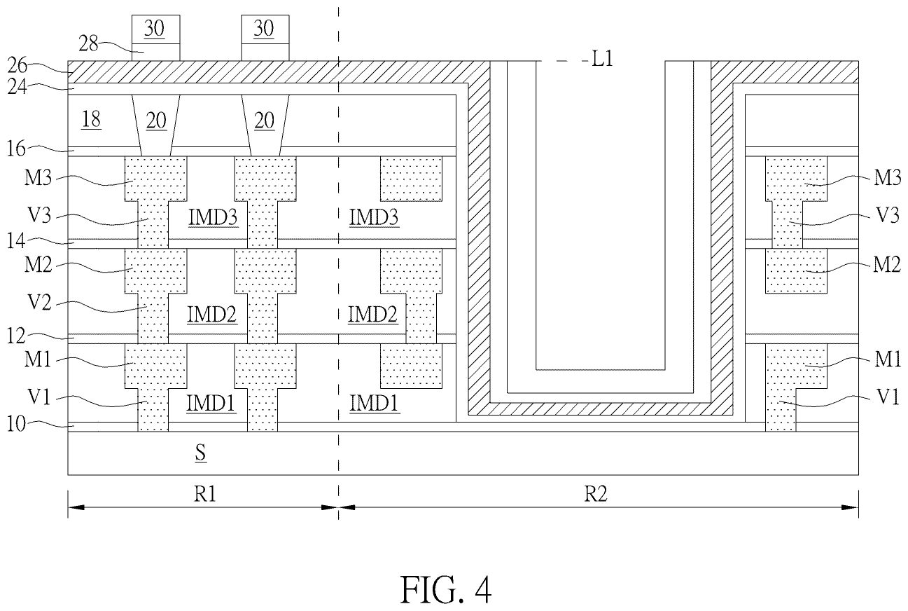

Then, as shown in FIG. 4, a patterning step is performed to remove part of the top electrode layer 28 and the mask layer 30 in the cell region R1, so as to define a predetermined pattern of the MTJ in the cell region R1, and remove the redundant top electrode layer 28 and the mask layer 30. At the same time, some steps are performed in the inductor region R2, when removing part of the top electrode layer 28 and the mask layer 30 in the cell region R1, the top electrode layer 28 and the mask layer 30 in the inductor region R2 are also removed. In this embodiment, at this time, the top surfaces of the top electrode layer 28 and the mask layer 30 in the inductor region R2 are flush with the top surface of the MTJ material layer 26 in the cell region R1 in the horizontal direction, as shown in the horizontal plane L1 shown in FIG. 4. However, the present invention is not limited to this. In other embodiments of the present invention, it is also possible to adjust the parameters during the patterning step so that the top surfaces of the top electrode layer 28 and the mask layer 30 in the inductor region R2 are not aligned with the top surfaces of the MTJ material layer 26 in the cell region R1, which is also within the scope of the present invention.

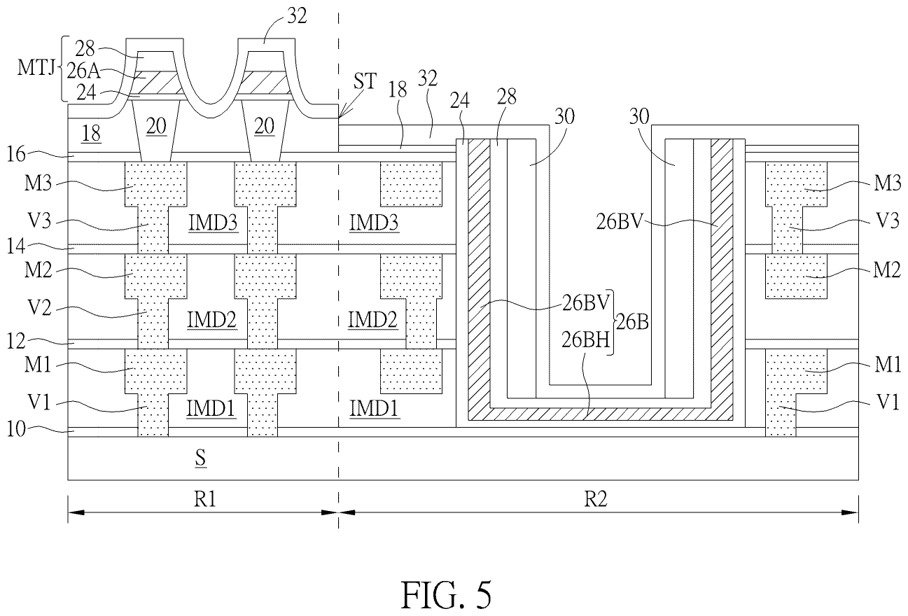

As shown in FIG. 5, using the mask layer 30 as a mask, an etching step is continued to remove part of the MTJ material layer 26, the bottom electrode layer 24 and the fourth dielectric layer 18 in the cell region R1. After that, the mask layer 30 is removed in a dry etching step. At this time, the remaining bottom electrode layer 24, MTJ material layer 26 and top electrode layer 28 in the cell region R1 are defined as the magnetic tunneling junction MTJ. The magnetic tunneling junction MTJ is electrically connected with the conductive via 20 below. After the etching step, the MTJ material layer 26 in the cell region R1 is separated from the MTJ material layer 26 in the inductor region R2. For convenience of distinction, the MTJ material layer 26 in the cell region R1 is defined as the MTJ material layer 26A, and the MTJ material layer 26 in the inductor region R2 is defined as the MTJ material layer 26B. Here, the MTJ material layer 26A will be used as a part of the magnetic tunneling junction MTJ, and the MTJ material layer 26B will be used as a part of the inductor to be formed later. It can be understood that the MTJ material layer 26A and the MTJ material layer 26B are made of the same material layer, so they comprise the same material. In addition, the MTJ material layer 26B has a U-shaped cross-section when viewed from the cross-section, so the MTJ material layer 26B has a horizontal portion 26BH and two vertical portions 26BV, wherein the horizontal portion 26BH and the two vertical portions 26BV together constitute the MTJ material layer 26B.

In addition, in the above dry etching step for removing the mask layer 30, because the etching process includes a vertical ion bombardment etching, when the mask layer 30 in the cell region R1 is completely removed, the mask layer 30 located on the bottom surface of the groove 22 in the inductor region R2 may also be completely removed, thus exposing the top surface of the top electrode layer 28 below, but some of the mask layers 30 in the sidewalls of the groove 22 have not been completely removed, but these mask layers 30 remain in the groove 22. Then, a nitride layer 32 is formed in the cell region R1 and the inductor region R2, and the nitride layer 32 covers the magnetic tunneling junctions MTJ and the material layers in the groove 22, such as the side surface of the mask layer 30 and the top surface of the top electrode layer 28. In this embodiment, the material of the nitride layer 32 includes silicon nitride.

In addition, in the etching process, after defining the required MTJ in the cell region R1, a mask layer (not shown) can be used to cover and protect the MTJ, and the mask layer can be removed before the nitride layer 32 is formed. Therefore, because the inductor region R2 is not covered by the mask layer, some material layers in the inductor region R2 will be etched more. For example, as shown in FIG. 5, the top surface of the fourth dielectric layer 18 in the inductor region R2 is lower than the top surface of the fourth dielectric layer 18 in the cell region R1, resulting in the formation of a stepped structure ST at the interface of the cell region R1 and the inductor region R2.

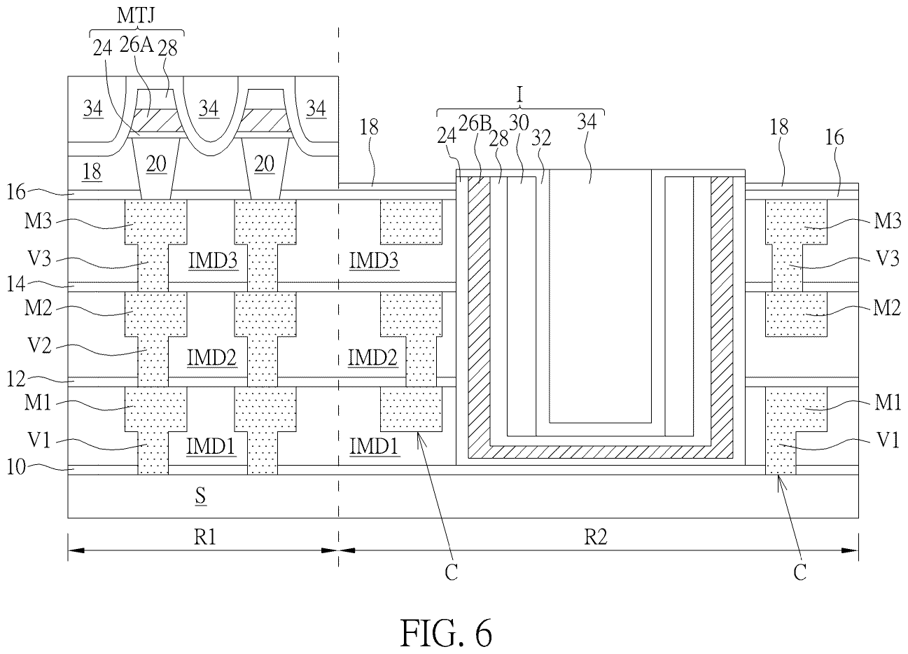

As shown in FIG. 6, an oxide layer 34 is then formed to fill the gaps between the MTJs and the grooves 22, where the oxide layer 34 can be performed by atomic layer deposition (ALD) because the gap size between the MTJs is small, but the present invention is not limited to this. The excess oxide layer 34 is subsequently removed. Up to this point, the bottom electrode layer 24, the MTJ material layer 26, the top electrode layer 28, the mask layer 30, the nitride layer 32 and the oxide layer 34 formed in the recess 22 are defined as inductor I. The inductor I comprises an MTJ material layer 26B, and the MTJ material layer 26B of the inductor I and the MTJ material layer 26A in the magnetic tunneling junction MTJ are formed at the same time, and both of them contain the same material. In addition, the inductor I is surrounded by the coil structure C. In addition, when the excess oxide layer 34 is removed, part of the nitride layer 32 may also be removed. In this embodiment, a part of the nitride layer 32 in the inductor region R2 is removed, but some nitride layer 32 still covers the top surfaces of the bottom electrode layer 24, the MTJ material layer 26B, the top electrode layer 28 and the mask layer 30.

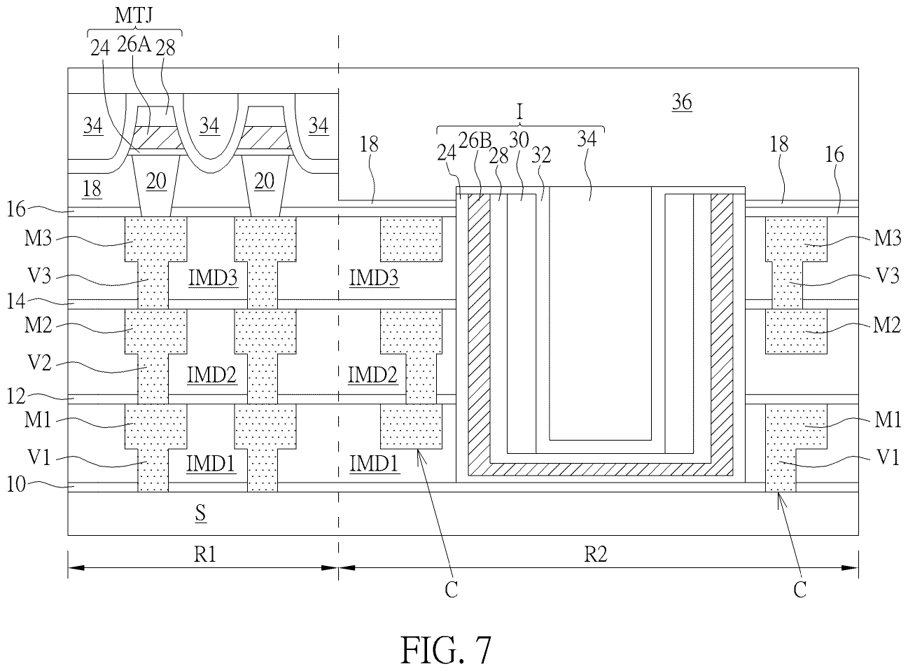

As shown in FIG. 7, a fifth dielectric layer 36 is formed in the cell region R1 and the inductor region R2, wherein the fifth dielectric layer 36 comprises an ultra-low dielectric constant material (ULK), such as silicon oxycarbide (SiCOH) or organosilicate glass (OSG), but the present invention is not limited to this.

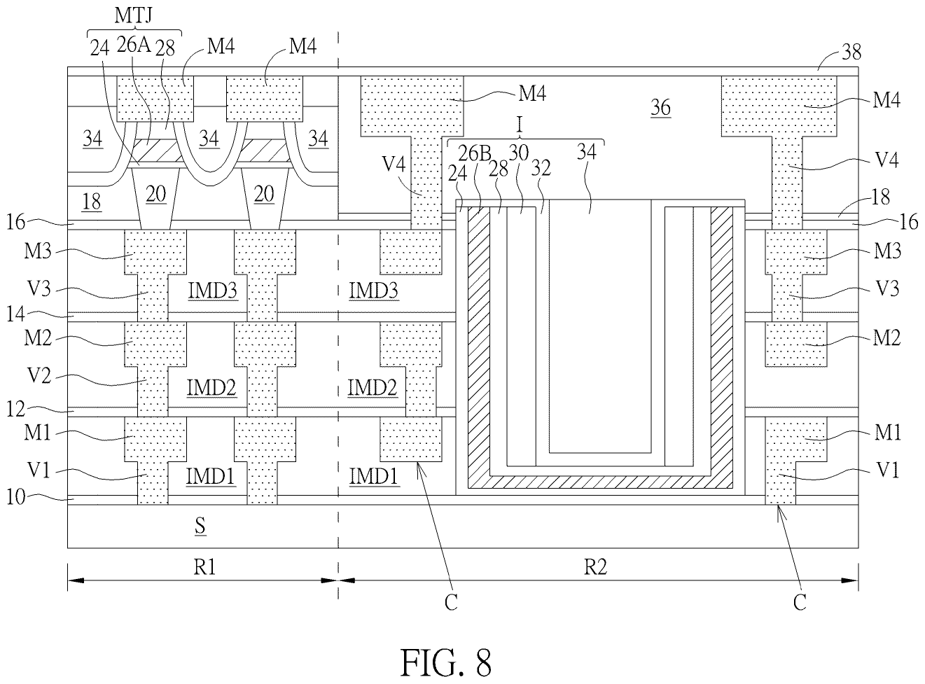

As shown in FIG. 8, a fourth metal layer M4 is formed in the cell region R1 and the inductor region R2, wherein the fourth metal layer M4 is electrically connected to the top electrode layer 28 of the magnetic tunneling junction MTJ. And a fourth metal layer M4 and a conductive via V4 are formed in the inductor region R2, wherein the conductive via V4 is electrically connected with the lower third metal layer M3. Then, a mask layer 38 is formed to cover the above structure. Up to this step, the semiconductor structure including MRAM and inductor in the present invention has been completed.

One of the characteristics of the present invention is that in the step of forming the magnetic tunneling junction MTJ, the inductor I can also be formed in the inductor region R2 next to the cell region R1 at the same time, so that the process steps can be saved. The inductor I contains the MTJ material layer 26B, and the MTJ material layer 26B contains magnetic materials such as CoPt (Cobalt Platinum) alloy, CoFe (Cobalt Iron) alloy, FePt (Iron Platinum) alloy, IrMn (Iridium Manganese) alloy, PtMn (Platinum Manganese) alloy, Co/Pt or Co/Pd multilayer film, etc. Therefore, the inductor I can be used to store magnetic energy. It is worth noting that the inductor I in this embodiment is not electrically connected with other elements, that is, the inductor I is in a floating state.

Another feature of the present invention is that the inductor I penetrates through multiple dielectric layers, that is to say, a part of each material layer of the inductor I extends along the vertical direction. Therefore, in a limited space, the vertical height of the inductor I is relatively high. Besides, the inductor I covers the side wall of the groove 22 (there are two vertical side walls in cross section), so the inductor I has a larger effective area, which can effectively increase the magnetic energy that the inductor I can store.

In addition, it is worth noting that the inductor I in this embodiment is mainly located in the first dielectric layer IMD1, the second dielectric layer IMD2 and the third dielectric layer IMD3, while the magnetic tunneling junction MTJ is located above the fourth dielectric layer 18 and at the same level as the fifth dielectric layer 36. That is to say, from the horizontal position, the horizontal position of the inductor I in this embodiment is lower than the horizontal position of the magnetic tunneling junction MTJ. In the conventional structure, the inductor may be formed in the same dielectric layer as the MTJ, and the space of the dielectric layer below the inductor cannot be used to accommodate components and becomes idle space. According to the invention, the space of the dielectric layer in the inductor region R2 is effectively utilized, and the space is used for setting the inductor I, so that the idle space in the inductor region R2 can be effectively utilized and the waste of space can be avoided.

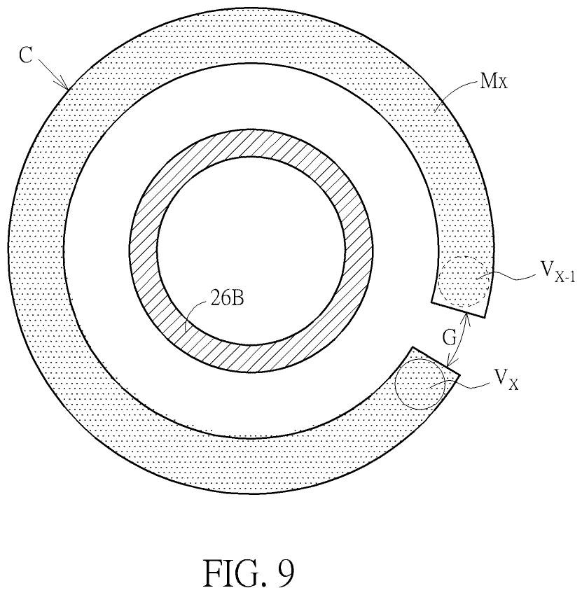

Please refer to FIG. 9, which shows the top view of the MTJ material layer and the coil structure C in the inductor region of the present invention. For the sake of clarity, FIG. 9 mainly shows the MTJ material layer 26B and the coil structure C in the inductor region, while other elements are omitted. As shown in FIG. 9, seen from the top view, the MTJ material layer 26B is, for example, annular, while the coil structure C includes an annular metal layer Mx with a gap G, and a conductive via Vx and a conductive via Vx-1 electrically connecting both ends of the annular metal layer Mx with a gap, where the annular metal layer Mx is, for example, the first metal layer M1, the second metal layer M2 or the third metal layer M3 shown in the above-mentioned FIGS. 1 to 8, while the conductive vias Vx and Vx-1 represent conductive vias connecting metal layers, such as conductive vias V1, V2, V3, V4, etc.

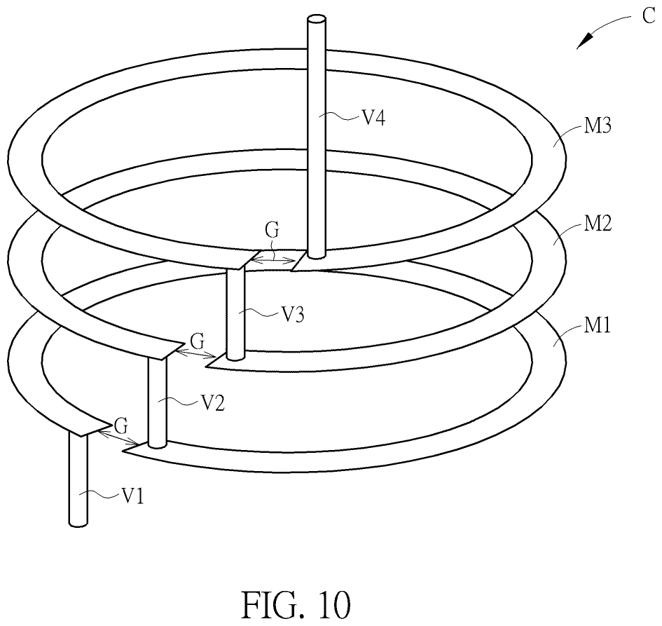

Please refer to FIG. 10, which shows the structural schematic diagram of the coil structure C of the present invention. Take the coil structure C shown in FIGS. 1 to 8 as an example. The coil structure C includes a first metal layer M1, a second metal layer M2 and a third metal layer M3, wherein each metal layer includes a gap G, and conductive vias are electrically connected at both ends of the gap of each metal layer for electrically connecting the metal layers with other metal layers. For example, both ends of the gap G of the second metal layer M2 are respectively connected with a conductive via V2 and a conductive via V3, so that the second metal layer is electrically connected with the first metal layer M1 and the third metal layer M3. By this arrangement, a plurality of metal layers can be connected in series to form a continuous spiral coil structure, and the coil structure surrounds the inductor I, so that a larger electric field can be generated when the coil structure C is energized, thereby improving the magnetic energy stored in the inductor I.

FIGS. 1 to 10 described above show a semiconductor structure including MRAM and inductor and its manufacturing method according to an embodiment of the present invention. In other embodiments of the present invention, changes can be made according to the above semiconductor structure. For example, it is also within the scope of the present invention to change the number of dielectric layers so that the semiconductor structure contains more or less dielectric layers, or to change the shape of the magnetic tunneling junction MTJ, inductor I or coil structure C, for example, from a ring shape to a frame shape when viewed from above.

In addition, in the present invention, the horizontal position of the inductor I is lower than the horizontal position of the magnetic tunneling junction MTJ, so that the idle dielectric layer space can be effectively utilized. In other embodiments of the present invention, the setting position of the inductor I can also be changed, for example, the horizontal position of the inductor I can be set higher than the horizontal position of the magnetic tunneling junction MTJ, so that the advantage of effective space utilization can also be achieved. This variation is also within the scope of the present invention.

Based on the above description and drawings, the semiconductor structure of the present invention includes a magnetic tunnel junction (MTJ) and an inductor, including a substrate S, a cell region R1 and an inductor region R2 defined on the substrate S are located next to the cell region R1, and a magnetic tunnel junction MTJ is located in the cell region R1. Wherein, the magnetic tunneling junction MTJ comprises a first MTJ material layer (namely, the MTJ material layer 26A in the magnetic tunneling junction MTJ located in the cell region R1), and an inductor I is located in the inductor region R2, wherein the inductor I comprises a multilayer structure, wherein the multilayer structure comprises at least a second MTJ material layer 26B, wher-ein the first MTJ material layer 26A is the same as the second MTJ material layer 26B, and from a sectional view, The first MTJ material layer 26A extends along a horizontal direction, and the second MTJ material layer 26B includes a horizontal part 26BH and two vertical parts 26BV, and the vertical part 26BV extends along a vertical direction.

In some embodiments of the present invention, the inductor I in the inductor region R2 is located in a first dielectric layer IMD1, and the magnetic tunneling junction MTJ in the cell region R1 is located in a fifth dielectric layer 26, wherein the first dielectric layer IMD1 and the fifth dielectric layer 36 are located in different levels.

In some embodiments of the present invention, the horizontal position of the first dielectric layer IMD1 is lower than that of the fifth dielectric layer 36.

In some embodiments of the present invention, a coil structure C is located in the inductor region R2, and the coil structure C is located around and surrounds the inductor I.

In some embodiments of the present invention, the coil structure C includes a plurality of annular pattern layers (such as the first metal layer M1, the second metal layer M2 and the third metal layer M3) arranged along the vertical direction, and each annular pattern layer includes a gap G when viewed from the top.

In some embodiments of the present invention, the two ends of the gap G of the annular pattern layer are defined as a head end and a tail end respectively, and at least one conductive via is further included to electrically connect the head end of one annular pattern layer and the tail end of another adjacent annular pattern layer, so that a plurality of annular pattern layers are electrically connected with each other and form a spiral structure (refer to FIGS. 9 and 10).

In some embodiments of the present invention, seen from a top view, the MTJ material layer 26B of the inductor I presents a ring pattern or a frame pattern, and includes an oxide layer 34 located in the middle of the ring pattern or the frame pattern.

In some embodiments of the present invention, the multilayer structure of the inductor I includes a bottom electrode layer 24, a second MTJ material layer 26B, a top electrode layer 28, a mask layer 30, a nitride layer 32 and an oxide layer 34, wherein, in cross section, the bottom electrode layer 24, the second MTJ material layer 26B, the top electrode layer 28 and the nitride layer 32 have a U-shaped profile, and the mask layer 30 has an I-shaped profile.

In some embodiments of the present invention, the nitride layer 32 covers a top surface of the bottom electrode layer 24, a top surface of the second MTJ material layer 26B, a top surface of the top electrode layer 28 and a top surface of the mask layer 30, but does not cover a top surface of the oxide layer 34.

The invention also provides a method for manufacturing a semiconductor structure including a magnetic tunnel junction (MTJ) and an inductor, which comprises providing a substrate S, wherein a cell region R1 and an inductor region R2 defined on the substrate S are located next to the cell region R1, and forming a magnetic tunnel junction MTJ located in the cell region R1, wherein the MTJ comprises a first MTJ material layer 26A, an inductor I is formed in the inductor region R2, wherein the inductor I comprises a multilayer structure, wherein the multilayer structure comprises at least a second MTJ material layer 26B, wherein the first MTJ material layer 26A and the second MTJ material layer 26B are made of the same material, and the first MTJ material layer 26A extends along a horizontal direction when viewed from a cross section, and the second MTJ material layer 26B comprises a horizontal part 26BH and two vertical parts 26BV, and the vertical part 26BV extends along a vertical direction.

In some embodiments of the present invention, the inductor I in the inductor region R2 is located in a first dielectric layer IMD1, and the magnetic tunneling junction MTJ in the cell region R1 is located in a fifth dielectric layer 26, wherein the first dielectric layer IMD1 and the fifth dielectric layer 36 are located in different levels.

In some embodiments of the present invention, the horizontal position of the first dielectric layer IMD1 is lower than that of the fifth dielectric layer 36.

In some embodiments of the present invention, it further includes forming a coil structure C located in the inductor region R2, and the coil structure C is located around and surrounds the inductor I.

In some embodiments of the present invention, the coil structure C includes a plurality of annular pattern layers (such as the first metal layer M1, the second metal layer M2 and the third metal layer M3) arranged along the vertical direction, and each annular pattern layer includes a gap G when viewed from the top.

In some embodiments of the present invention, the two ends of the gap G of the annular pattern layer are defined as a head end and a tail end respectively, and at least one conductive via is further included to electrically connect the head end of one annular pattern layer and the tail end of another adjacent annular pattern layer, so that a plurality of annular pattern layers are electrically connected with each other and form a spiral structure (refer to FIGS. 9 and 10).

In some embodiments of the present invention, at least one conductor layer (including the first metal layer M1, the second metal layer M2 and the third metal layer M3 in the cell region, etc.) is formed below the magnetic tunneling junction MTJ in the cell region R1, and the conductor layer is electrically connected with the magnetic tunneling junction MTJ, wherein the conductor layer and one of a plurality of annular pattern layers of the coil structure C are formed at the same time (that is, at least one of the first metal layer M1, the second metal layer M2 and the third metal layer M3 is simultaneously formed in the cell region R1 and the inductor region R2).

In some embodiments of the present invention, seen from a top view, the MTJ material layer 26B of the inductor I presents a ring pattern or a frame pattern, and includes an oxide layer 34 located in the middle of the ring pattern or the frame pattern.

In some embodiments of the present invention, the multilayer structure of the inductor I includes a bottom electrode layer 24, a second MTJ material layer 26B, a top electrode layer 28, a mask layer 30, a nitride layer 32 and an oxide layer 34, wherein, in cross section, the bottom electrode layer 24, the second MTJ material layer 26B, the top electrode layer 28 and the nitride layer 32 have a U-shaped profile, and the mask layer 30 has an I-shaped profile.

In some embodiments of the present invention, the nitride layer 32 covers a top surface of the bottom electrode layer 24, a top surface of the second MTJ material layer 26B, a top surface of the top electrode layer 28 and a top surface of the mask layer 30, but does not cover a top surface of the oxide layer 34.

In some embodiments of the present invention, the first MTJ material layer 26A of the magnetic tunneling junction and the second MTJ material layer 26B in the inductor I are formed at the same time.

To sum up, the invention provides a semiconductor structure integrated with MRAM and inductor and a manufacturing method thereof. In which an inductor is formed in the process of manufacturing MRAM, so that the process steps can be saved. In addition, the inductors are arranged along the vertical direction and vertically penetrate through the multilayer dielectric layers, thus effectively utilizing the idle space in the stacked dielectric layers. In addition, the inductor of the invention is surrounded by a spiral coil structure, wherein the coil structure is formed by connecting a plurality of notched metal layers and conductive vias in series, so that when the coil structure is electrified, a larger electric field can be generated to improve the magnetic energy stored in the inductor. Therefore, the invention has the effects of improving semiconductor quality and simplifying manufacturing process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure including a magnetic tunnel junction (MTJ) and an inductor, comprising:
a substrate, on which a cell region and an inductor region are defined, and the inductor region is located beside the cell region;
a magnetic tunneling junction (MTJ) located in the cell region, wherein the magnetic tunneling junction contains a first MTJ material layer; and
an inductor located in the inductor region, wherein the inductor comprises a multilayer structure, wherein the multilayer structure comprises at least a second MTJ material layer, wherein the material of the first MTJ material layer is the same as the material of the second MTJ material layer, and the first MTJ material layer extends along a horizontal direction when viewed from a cross section, and the second MTJ material layer comprises a horizontal part and two vertical parts, and the vertical parts extend along a vertical direction.

2. The semiconductor structure including a magnetic tunnel junction and an inductor according to claim 1, wherein the inductor in the inductor region is located in a first dielectric layer, and the magnetic tunneling junction in the cell region is located in a fifth dielectric layer, wherein the first dielectric layer and the fifth dielectric layer are located at different levels.

3. The semiconductor structure including a magnetic tunnel junction and an inductor according to claim 2, wherein the horizontal position of the first dielectric layer is lower than the horizontal position of the fifth dielectric layer.

4. The semiconductor structure including a magnetic tunnel junction and an inductor according to claim 1, further comprising a coil structure located in the inductor region, wherein the coil structure is located around and surrounds the inductor.

5. The semiconductor structure including a magnetic tunnel junction and an inductor according to claim 4, wherein the coil structure comprises a plurality of annular pattern layers arranged along the vertical direction, and each annular pattern layer comprises a gap when viewed from the top.

6. The semiconductor structure including a magnetic tunnel junction and an inductor according to claim 5, wherein both ends of the gap of the annular pattern layer are defined as a head end and a tail end respectively, and further comprises at least one conductive via electrically connecting the head end of one of the annular pattern layers and the tail end of another adjacent annular pattern layer, and the annular pattern layers are electrically connected with each other and form a spiral structure.

7. The semiconductor structure including a magnetic tunnel junction and an inductor according to claim 1, wherein when viewed from a top view, the second MTJ material layer contained in the inductor presents a ring pattern or a frame pattern, and an oxide layer is located in the middle of the ring pattern or the frame pattern.

8. The semiconductor structure including a magnetic tunnel junction and an inductor according to claim 1, wherein the multilayer structure of the inductor comprises a bottom electrode layer, the second MTJ material layer, a top electrode layer, a mask layer, a nitride layer and an oxide layer, wherein the cross sections of the bottom electrode layer, the second MTJ material layer, the top electrode layer and the nitride layer are U-shaped, and the mask layer is I-shaped.

9. The semiconductor structure including a magnetic tunnel junction and an inductor according to claim 8, wherein the nitride layer covers a top surface of the bottom electrode layer, a top surface of the second MTJ material layer, a top surface of the top electrode layer and a top surface of the mask layer, but does not cover a top surface of the oxide layer.

10. A manufacturing method of a semiconductor structure including a magnetic tunnel junction (MTJ) and an inductor, comprising:
providing a substrate having defined thereon a cell region and an inductor region located beside the cell region;
forming a magnetic tunneling junction (MTJ) in the cell region, wherein the magnetic tunneling junction contains a first MTJ material layer; and
forming an inductor in the inductor region, wherein the inductor comprises a multilayer structure, wherein the multilayer structure comprises at least a second MTJ material layer, wherein the material of the first MTJ material layer is the same as the material of the second MTJ material layer, and the first MTJ material layer extends along a horizontal direction when viewed from a cross section, and the second MTJ material layer comprises a horizontal part and two vertical parts, and the vertical parts extend along a vertical direction.

11. The method for manufacturing a semiconductor structure including a magnetic tunnel junction and an inductor according to claim 10, wherein the inductor in the inductor region is located in a first dielectric layer, and the magnetic tunneling junction in the cell region is located in a fifth dielectric layer, wherein the first dielectric layer and the fifth dielectric layer are located at different levels.

12. The method for manufacturing a semiconductor structure including a magnetic tunnel junction and an inductor according to claim 11, wherein the horizontal position of the first dielectric layer is lower than the horizontal position of the fifth dielectric layer.

13. The method for manufacturing a semiconductor structure including a magnetic tunnel junction and an inductor according to claim 10, further comprising forming a coil structure in the inductor region, which is located around and surrounds the inductor.

14. The method for manufacturing a semiconductor structure including a magnetic tunnel junction and an inductor according to claim 13, wherein the coil structure comprises a plurality of annular pattern layers arranged along the vertical direction, and each annular pattern layer comprises a gap when viewed from the top.

15. The method for manufacturing a semiconductor structure including a magnetic tunnel junction and an inductor according to claim 14, wherein both ends of the gap of the annular pattern layer are defined as a head end and a tail end respectively, and further comprises forming at least one conductive via to electrically connect the head end of one of the annular pattern layers and the tail end of another adjacent annular pattern layer, so that the annular pattern layers are electrically connected with each other and form a spiral structure.

16. The method for manufacturing a semiconductor structure including a magnetic tunnel junction and an inductor according to claim 14, further comprising forming at least one conductor layer below the magnetic tunneling junction in the cell region and electrically connected with the magnetic tunneling junction, wherein the conductor layer is formed simultaneously with one of the plurality of annular pattern layers of the coil structure.

17. The method for manufacturing a semiconductor structure including a magnetic tunnel junction and an inductor according to claim 10, wherein, when viewed from a top view, the second MTJ material layer contained in the inductor presents a ring pattern or a frame pattern, and an oxide layer is located in the middle of the ring pattern or the frame pattern.

18. The method for manufacturing a semiconductor structure including a magnetic tunnel junction and an inductor according to claim 10, wherein the multilayer structure of the inductor comprises a bottom electrode layer, the second MTJ material layer, a top electrode layer, a mask layer, a nitride layer and an oxide layer, wherein the cross sections of the bottom electrode layer, the second MTJ material layer, the top electrode layer and the nitride layer are U-shaped, and the mask layer is I-shaped.

19. The method for manufacturing a semiconductor structure including a magnetic tunnel junction and an inductor according to claim 18, wherein the nitride layer covers a top surface of the bottom electrode layer, a top surface of the second MTJ material layer, a top surface of the top electrode layer and a top surface of the mask layer, but does not cover a top surface of the oxide layer.

20. The method for manufacturing a semiconductor structure including a magnetic tunnel junction and an inductor according to claim 10, wherein the first MTJ material layer of the magnetic tunneling junction and the second MTJ material layer of the inductor are simultaneously formed.
